(19) United States
(12) Patent Application Publication
(10) Pub. No.: US 2026/0299572 A1
(43) Pub. Date: Oct. 1, 2026

(54) SUBSTRATE TRANSPORT SYSTEM AND SUBSTRATE TRANSPORT METHOD

(71) Applicant: KAWASAKI JUKOGYO KABUSHIKI KAISHA, Kobe-shi, Hyogo (JP)

(72) Inventor: Kazuo FUJIMORI, Kobe-shi (JP)

(73) Assignee: KAWASAKI JUKOGYO KABUSHIKI KAISHA, Kobe-shi, Hyogo (JP)

(21) Appl. No.: 19/489,049

(22) PCT Filed: May 29, 2024
(86) PCT No.: PCT/JP2024/019722

§ 371 Date: Dec. 1, 2025

(30) Foreign Application Priority Data
Jun. 1, 2023 (JP) 2023-090761

(51) Int. Cl. G05B 19/418

(52) U.S. Cl. CPC G05B 19/4189; G05B 2219/32335; G05B 2219/39001

(57) ABSTRACT

A substrate transport system includes a detector to detect at least one of a substrate transported by a substrate transport robot or a substrate mount on which the substrate is placed. The substrate transport system also includes a controller configured or programmed to generate a trained model by machine learning to output transport control information for controlling transport operation of the substrate by the substrate transport robot using a result of detection by the detector as an input.

### TECHNICAL FIELD

The present disclosure relates to a substrate transport system and a substrate transport method.

### BACKGROUND ART

Conventionally, a substrate transport method for transporting a substrate is disclosed. Japanese Patent No. 6640321 discloses a substrate transport method for transporting a substrate to a mounting table in a substrate processing chamber in which the substrate is processed using a transport robot arranged in a substrate transport chamber. The transport robot includes a fork on which a substrate is placed, and a position sensor is disposed in the substrate transport chamber to detect the substrate placed on the fork. In the substrate transport method described in Japanese Patent No. 6640321, the substrate placed on the fork is detected by the position sensor, and a path of substrate transport by the transport robot is corrected so as to correct the positional deviation of the substrate with respect to the fork.

### PRIOR ART

### Patent Document

Patent Document 1: Japanese Patent No. 6640321

### SUMMARY OF THE INVENTION

However, when the transport operation of the substrate is performed, it is necessary to teach the transport operation to a substrate transport robot, which is a transport robot that transports a substrate. In Japanese Patent No. 6640321, while the position sensor detects any positional deviation of the substrate with respect to the fork that holds the substrate, it is necessary to manually teach the transport operation to the substrate transport robot. Therefore, it is necessary to teach the transport operation for each configuration of a substrate transport system, such as the position of a substrate mount, and thus the effort required to teach the transport operation to the substrate transport robot conceivably imposes a burden on an operator. Therefore, it is desired to reduce the effort required by the operator to control the transport operation of the substrate by the substrate transport robot.

The present disclosure is intended to solve the above problems. The present disclosure aims to provide a substrate transport system and a substrate transport method each capable of reducing the effort required by an operator to control the transport operation of a substrate by a substrate transport robot.

A substrate transport system according to a first aspect of the present disclosure includes a substrate transport robot, a detector to detect at least one of a substrate transported by the substrate transport robot or a substrate mount on which the substrate is placed, and a controller configured or programmed to generate a trained model by machine learning to output transport control information for controlling transport operation of the substrate by the substrate transport robot using a result of detection of the at least one of the substrate or the substrate mount by the detector as an input.

As described above, the substrate transport system according to the first aspect of the present disclosure is configured to generate the trained model by machine learning to output the transport control information for controlling the transport operation of the substrate by the substrate transport robot using the result of detection of at least one of the substrate or the substrate mount by the detector as an input. Accordingly, the transport operation of the substrate can be automatically controlled based on the output from the trained model generated by machine learning.

Consequently, the effort required by an operator to control the transport operation of the substrate by the substrate transport robot can be reduced, as compared with a case in which the transport operation of the substrate to the substrate mount is manually taught.

A substrate transport method according to a second aspect of the present disclosure includes detecting at least one of a substrate transported by a substrate transport robot or a substrate mount on which the substrate is placed, and generating a trained model by machine learning to output transport control information for controlling transport operation of the substrate by the substrate transport robot using a result of detection of the at least one of the substrate or the substrate mount by the detector as an input.

As described above, the substrate transport method according to the second aspect of the present disclosure includes generating the trained model by machine learning to output the transport control information for controlling the transport operation of the substrate by the substrate transport robot using the result of detection of at least one of the substrate or the substrate mount as an input. Accordingly, the transport operation of the substrate can be automatically controlled based on the output from the trained model generated by machine learning. Consequently, it is possible to provide the substrate transport method capable of reducing the effort required by an operator to control the transport operation of the substrate by the substrate transport robot, as compared with a case in which the transport operation of the substrate to the substrate mount is manually taught.

According to the present disclosure, it is possible to reduce the effort required by the operator to control the transport operation of the substrate by the substrate transport robot.

### BRIEF DESCRIPTION OF THE DRAWINGS

FIG. 1 is a top view showing a substrate processing system in which a substrate transport system according to an embodiment of the present disclosure is disposed.

FIG. 2 is a block diagram showing the configuration of the substrate transport system according to the embodiment of the present disclosure.

FIG. 3 is a perspective view schematically showing the configuration of the substrate transport system.

FIG. 4 shows an example of an image of a FOUP captured by an imager placed in a transport chamber.

FIG. 5 shows an example of an image of a load lock captured by the imager placed in the transport chamber.

FIG. 6 shows an example of an image of an aligner captured by the imager placed in the transport chamber.

FIG. 7 shows an example of an image captured by an imager placed in a substrate transport robot.

FIG. 8 is a diagram for illustrating an output of transport control information based on a trained model.

FIG. 9 shows an example of the positional deviation of a substrate with respect to a substrate mount.

FIG. 10 shows an example of the positional deviation of a substrate with respect to a substrate mount.

FIG. 11 is a flowchart for illustrating a substrate transport method according to the present embodiment.

### MODES FOR CARRYING OUT THE INVENTION

An embodiment embodying the present disclosure is hereinafter described on the basis of the drawings.

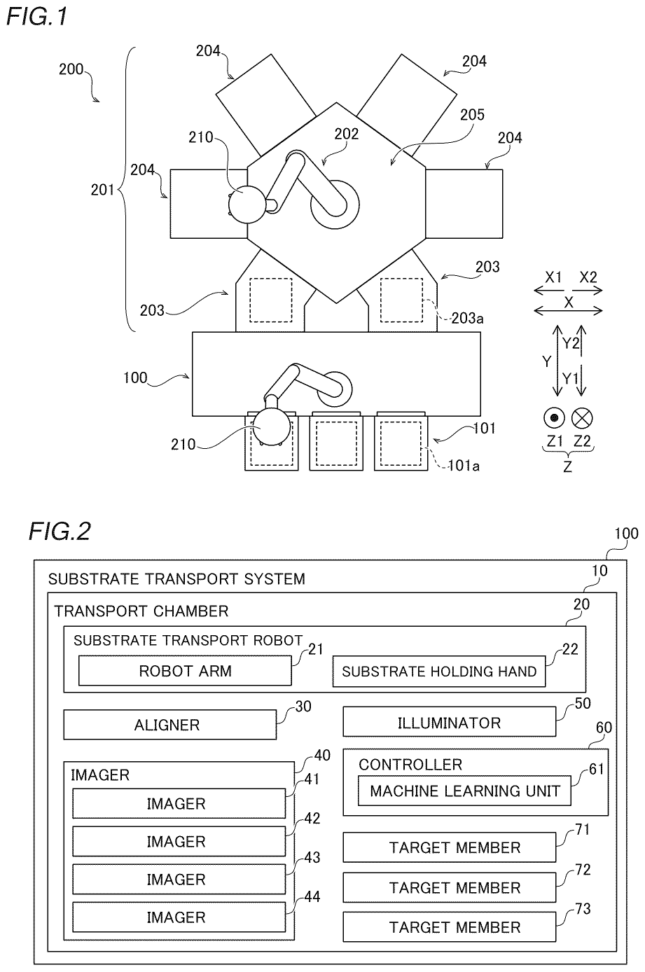

A substrate transport system 100 according to the present embodiment is now described with reference to FIGS. 1 to 10.

### Substrate Processing System

As shown in FIG. 1, the substrate transport system 100 is disposed in a substrate processing system 200. The substrate processing system 200 includes a processing apparatus 201 that processes a substrate 210. The processing apparatus 201 includes a substrate transport robot 202, load locks 203, a plurality of processing modules 204, and a transport chamber 205. The substrate transport robot 202 is a horizontal articulated robot that transports the substrate 210. The load locks 203 are chambers to load and unload the substrate 210. That is, the substrate 210 is placed in the load lock 203 to be delivered to the processing apparatus 201. The processing apparatus 201 of the substrate processing system 200 includes two load locks 203. The load locks 203 are connected to the substrate transport system 100. The load locks 203 each include a substrate mount 203a on which the substrate 210 is placed. In the processing modules 204, a process such as resist coating or etching is performed on the substrate 210. The substrate transport robot 202 is disposed in the transport chamber 205. In the transport chamber 205, the substrate transport robot 202 transports the substrate 210 between the load locks 203 and the processing modules 204. The load locks 203 are examples of a processing standby unit.

The substrate transport system 100 transports the substrate 210 between a FOUP 101 (Front Opening Unify Pod) and the processing apparatus 201 in the substrate processing system 200 in which the process is performed on the substrate 210. The substrate transport system 100 is an EFEM (Equipment Front End Module). The FOUP 101 is a container that stores a plurality of substrates 210. The FOUP 101 includes a substrate mount 101a on which the substrate 210 is placed. In the FOUP 101, the plurality of substrates 210 are aligned in an upward-downward direction. The FOUP 101 is an example of a substrate storage container. The substrate 210 is a disk-shaped silicon wafer, for example.

### Substrate Transport System

As shown in FIG. 2, the substrate transport system 100 includes a transport chamber 10, a substrate transport robot 20, an aligner 30, an imager 40, illuminators 50, and a controller 60. The substrate transport system 100 includes target members 71, target members 72, and target members 73. The substrate transport robot 20 includes a horizontal articulated robot arm 21 and a substrate holding hand 22. The imager 40 includes imagers 41, 42, 43, and 44. The imager 40 is an example of a detector.

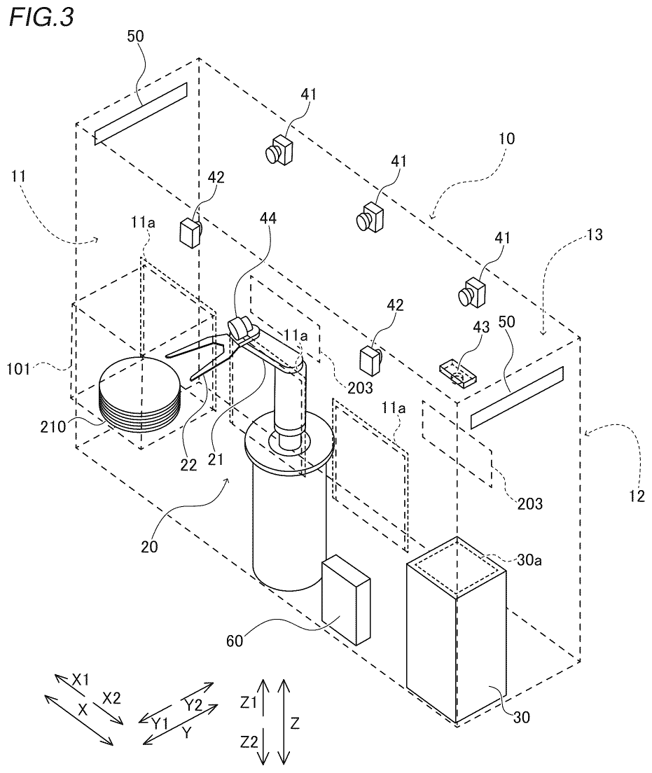

As shown in FIG. 3, the transport chamber 10 is a rectangular parallelepiped housing. The transport chamber 10 includes a front surface 11 on the Y1 side and a back surface 12 on the Y2 side. The transport chamber 10 also includes a top surface 13 on the vertically upper side, i.e., the Z1 side. The substrate 210 is transported within the transport chamber 10. The transport chamber 10 houses the substrate transport robot 20, the aligner 30, the imager 40, the illuminators 50, and the controller 60. Three load ports 11a, to which FOUPs 101 are attached, are aligned horizontally on the front surface 11 of the transport chamber 10 on the Y1 side. Each load port 11a includes an opening/closing mechanism. Each load port 11a opens and closes a door of the attached FOUP 101. The two load locks 203 are connected to the back surface 12 of the transport chamber 10 on the Y2 side. An opening/closing mechanism is also disposed between the load locks 203 and the back surface 12. FIG. 3 shows a state in which the FOUP 101 is attached to one of the three load ports 11a on the X1 direction side.

The substrate transport robot 20 is arranged in the transport chamber 10. The substrate transport robot 20 performs the transport operation of the substrate 210 in the transport chamber 10. Specifically, in the substrate transport robot 20, the substrate holding hand 22, which is an end effector to hold the substrate 210, is disposed at the distal end of the robot arm 21. The substrate transport robot 20 performs the transport operation of the substrate 210 between the FOUP 101 attached to the load port 11a and the load lock 203. The substrate transport robot 20 transports the substrate 210 while holding the substrate 210 along a horizontal plane in the substrate holding hand 22.

The aligner 30 aligns the substrate 210 transported by the substrate transport robot 20. In the transport chamber 10, the aligner 30 is located to the X2 direction side, which is one side in an X direction in right-left direction. The aligner 30 includes a substrate mount 30a on which the substrate 210 is placed. The aligner 30 rotates the substrate 210 placed on the substrate mount 30a along the horizontal plane to align the rotational position along the circumferential direction of the main surface of the substrate 210. The aligner 30 also detects the central position of the substrate 210.

In the substrate transport system 100, the substrate 210 held by the substrate transport robot 20 from the FOUP 101 is transported to the aligner 30. The substrate 210 aligned by the aligner 30 is then transported to the load lock 203 by the substrate transport robot 20 again. Furthermore, the substrate 210 on which the process has been performed in the processing apparatus 201 is transported from the load lock 203 to the FOUP 101 by the substrate transport robot 20. The transfer operation of the substrate 210 by the substrate transport robot 20 includes both an operation to carry out the substrate 210 by taking out the substrate 210 placed on each of the substrate mount 101a of the FOUP 101, the substrate mount 203a of the load lock 203, and the substrate mount 30a of the aligner 30, and an operation to carry in the substrate 210 by placing the substrate 210 on each of the substrate mount 101a of the FOUP 101, the substrate mount 203a of the load lock 203, and the substrate mount 30a of the aligner 30.

The imager 40 includes a two-dimensional camera, for example. Each of the imagers 41, 42, 43, and 44 of the imager 40 includes an imaging device such as a charge-coupled device (CCD) or a complementary metal-oxide semiconductor (CMOS). The imagers 41, 42, and 43 are disposed on an upper portion of the transport chamber 10. The imager 44 is disposed on the substrate holding hand 22 of the substrate transport robot 20. Specifically, three imagers 41 are disposed on the upper side of the back surface 12 in a Z1 direction within the transport chamber 10, corresponding to the three load ports 11a to which the FOUPs 101 are attached. The imagers 41 capture images of the FOUPs 101. Two imagers 42 are disposed on the upper side of the front surface 11 in the Z1 direction within the transport chamber 10, corresponding to the two load locks 203. The imagers 41 image the load locks 203. The imager 43 is disposed above the aligner 30 on the top surface 13 within the transport chamber 10. The imager 43 images the aligner 30. The imager 44 is disposed on the Z1 direction side of the substrate holding hand 22. The imager 44 is fixed to the substrate holding hand 22 so as to move integrally with the substrate holding hand 22. The imagers 41, 42, and 43 are examples of a transport chamber imager. The imager 44 is an example of a robot imager.

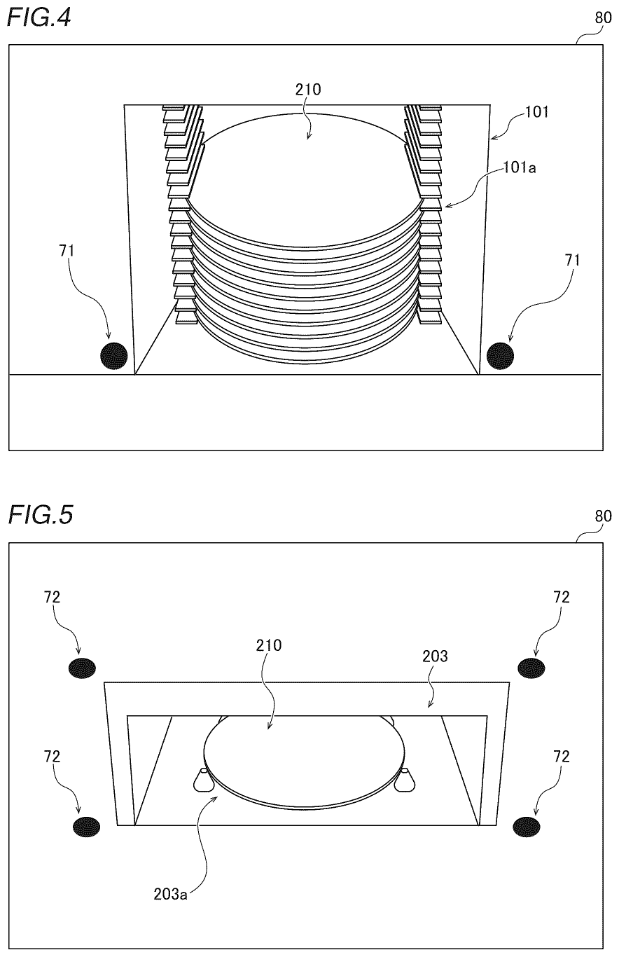

As shown in FIG. 4, a captured image 80 is acquired by imaging with the imager 40. FIG. 4 shows an example of the captured image 80 of the FOUP 101 captured by the imager 41 of the imager 40. The captured image 80 captured by each of the imagers 41, 42, 43, and 44 of the imager 40 is transmitted to the controller 60.

The captured image 80 captured by the imager 41 includes the substrates 210 stored in the FOUP 101, the substrate mounts 101a in the FOUP 101, and the target members 71. The target members 71 are members that indicate the positions of the substrate mounts 101a in the FOUP 101. In other words, the imager 41 images the substrates 210 stored in the FOUP 101, the substrate mounts 101a in the FOUP 101, and the target members 71 by imaging the FOUP 101. Regarding the FOUP 101, the target members 71 are arranged, for example, on the front surface 11 within the transport chamber 10, one on each side of one load port 11a in the X direction in the right-left direction.

As shown in FIG. 5, a captured image 80 of the load lock 203 captured by the imager 42 includes the substrate 210 placed in the load lock 203, the substrate mount 203a in the load lock 203, and the target members 72. That is, the imager 42 images the substrate 210 placed in the load lock 203, the substrate mount 203a in the load lock 203, and the target members 72 by imaging the load lock 203 from inside the transport chamber 10. Regarding the load lock 203, the target members 72 are arranged, for example, on the back surface 12 within the transport chamber 10, two on each side of the load lock 203 in the X direction in the right-left direction, i.e. at the four corners of the load lock 203.

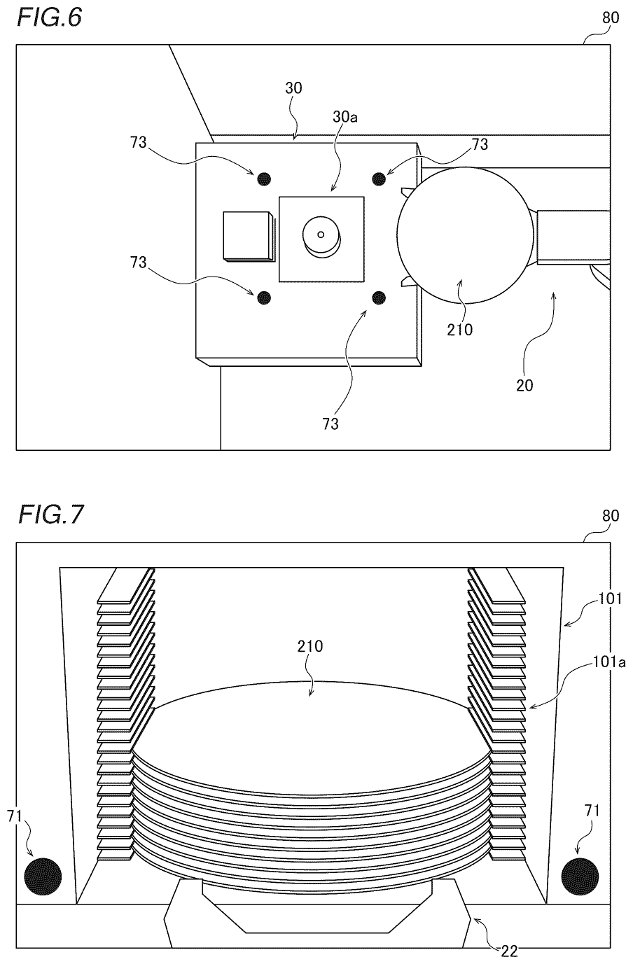

As shown in FIG. 6, a captured image 80 of the aligner 30 captured by the imager 43 includes the substrate 210 placed on the aligner 30, the substrate mount 30a in the aligner 30, and the target members 73. That is, the imager 43 images the substrate 210 placed on the substrate mount 30a, the substrate mount 30a, and the target members 73 by imaging the aligner 30 from the top surface 13 inside the transport chamber 10. Regarding the aligner 30, the target members 72 are arranged, for example, at the four corners of the substrate mount 30a in the aligner 30 within the transport chamber 10.

Since the substrate transport robot 20 is disposed within the transport chamber 10, the substrate transport robot 20 may be included in the captured image 80 captured by each of the imagers 41, 42, and 43. In the example of FIG. 6, the substrate transport robot 20, which is operating to bring the substrate holding hand 22 holding the substrate 210 closer to the aligner 30, is included in the captured image 80 captured by the imager 43. The imagers 41, 42, and 43 are disposed in a fixed state within the transport chamber 10, and imaging target areas to be imaged by the imagers 41, 42, and 43 are fixed.

As shown in FIG. 7, the captured image 80 captured by the imager 44 is an image captured with an imaging direction being a direction from the proximal end to the distal end of the substrate holding hand 22 of the substrate transport robot 20. For example, when the substrate transport robot 20 performs an operation to take out the substrate 210 from the FOUP 101, the captured image 80 captured by the imager 44 includes the substrate mounts 101a of the FOUP 101, the substrates 210 placed on the substrate mounts 101a, and the target members 71. The captured image 80 captured by the imager 44 includes the distal end portion of the substrate holding hand 22 of the substrate transport robot 20. The imaging direction of the imager 44 changes according to the operation of the substrate holding hand 22.

As shown in FIG. 3, the illuminators 50 emit illumination light in the transport chamber 10. The illuminators 50 each include, for example, a light-emitting diode (LED) that emits yellow light as illumination light. The illuminators 50 emit illumination light at the timing at which imaging is performed by the imager 40. The illuminators 50 emit illumination light to an area to be captured by the imager 40, for example, by emitting diffused illumination light to the entire interior of the transport chamber 10. One illuminator 50 is disposed on each of the side surfaces in X1 and X2 directions on the upper side in the Z1 direction within the transport chamber 10. The captured image 80 captured by the imager 40 while illumination light is emitted from the illuminators 50 is transmitted to the controller 60.

As shown in FIG. 1, the controller 60 includes a machine learning unit 61. The controller 60 controls the operation of each portion of the substrate transport system 100. In this embodiment, the controller 60 is a robot controller that controls the operation of the substrate transport robot 20. That is, the controller 60 is a robot controller. The controller 60 includes, for example, an arithmetic unit such as a central processing unit (CPU). The controller 60 also includes memories such as a random access memory (RAM) and a read-only memory (ROM) and a storage device such as a hard disk. The controller 60 executes a control process using the arithmetic unit based on programs and parameters stored in the storage device, for example. In this embodiment, the controller 60 controls capturing of the captured image 80 by the imager 40 and controls the transport operation of the substrate 210 by the substrate transport robot 20. For example, the controller 60 includes a main CPU that controls capturing of the captured image 80, controls machine learning described below, and controls generation of command values for the transport operation of the substrate 210, and a servo CPU that controls a drive current output to a servomotor that serves as a drive source for operating the substrate transport robot 20, based on the command values for the transport operation from the main CPU. The controller 60 may include a single CPU.

### Control of Transport Operation

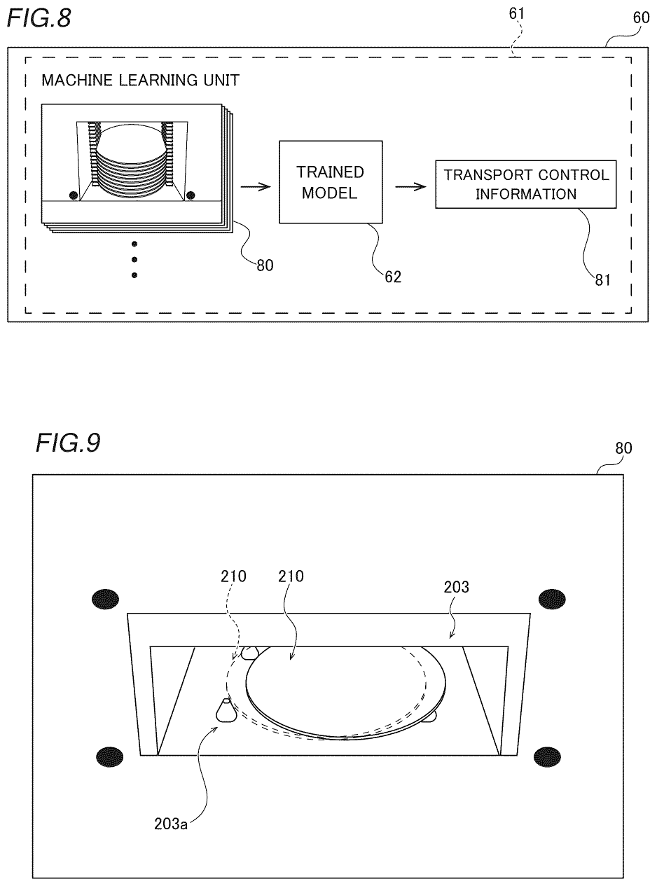

As shown in FIG. 8, in this embodiment, the controller 60 acquires transport control information 81 for controlling the transport operation of the substrate transport robot 20 based on a trained model 62 generated by machine learning using the captured images 80 captured by the imager 40. The trained model 62 receives the captured image 80 captured by each of the imagers 41, 42, 43, and 44 of the imager 40 and outputs the transport control information 81 for controlling the transport operation of the substrate transport robot 20. The transport control information 81 includes teaching information for aligning the coordinate axes of the substrate transport robot 20 with the coordinate axes of the positions of the substrate mounts 101a, the substrate mount 203a, and the substrate mount 30a. The transport control information 81 includes information indicating the positions of the substrates 210 on the coordinate axes of the substrate transport robot 20, and information indicating the positions of the substrate mounts 101a, the substrate mount 203a, and the substrate mount 30a. The transport control information 81 includes, for example, command values as control amounts for operating the robot arm 21 of the substrate transport robot 20. Specifically, the transport control information 81 includes command values for controlling the rotation angle of a motor that serves as a drive source for the robot arm 21. The trained model 62 is generated by the machine learning unit 61 of the controller 60 and is stored in the storage device of the controller 60.

### Generation of Trained Model

In the controller 60, the machine learning unit 61 generates the trained model 62 by machine learning. In the machine learning unit 61, the trained model 62 is generated by machine learning using deep reinforcement learning to output the transport control information 81 using the captured images 80 as inputs. The machine learning unit 61 performs machine learning using a Deep Q-Network (DQN), a form of reinforcement learning using deep learning, for example. In deep reinforcement learning, the machine learning unit 61 generates the trained model 62 by learning the transport control information 81 through repeated trials based on the captured images 80.

In deep reinforcement learning, the controller 60 acquires in advance, as target teaching images, captured images 80 in which the center position of the substrate holding hand 22 is located at the center positions of the substrate mounts 101a, the center position of the substrate mount 203a, and the center position of the substrate mount 30a, or captured images 80 in which the holding center position of the substrate holding hand 22 is aligned with the center positions of the placed substrates 210, for example. Then, in deep reinforcement learning by the machine learning unit 61 of the controller 60, the captured image 80 captured by each of the imagers 41, 42, 43, and 44 is used as an input, and machine learning is performed by operating the substrate transport robot 20 through repeated trials, for example, by evaluating a value indicating the degree of match between the input captured image 80 and the teaching image acquired in advance. For example, the degree of match is evaluated based on the positional relationship between each of the target members 71, 72, and 73 and the substrate 210 or the substrate holding hand 22. In deep reinforcement learning, the trained model 62 is generated by repeated trials to obtain a higher evaluation.

In this embodiment, each of the target members 71, 72, and 73 is a plate-shaped member having a predetermined circular shape in the captured image 80, for example, so as to be identified by the controller 60 in machine learning that generates the trained model 62. Furthermore, each of the target members 71, 72, and 73 has a color different from the surrounding area, so as to be identified in the captured image 80. For example, each of the target members 71, 72, and 73 is black. The controller 60 detects the substrate(s) 210 included in the captured image 80.

The machine learning unit 61 of the controller 60 performs machine learning using deep reinforcement learning to learn by repeatedly attempting the transport operation of the substrate transport robot 20 including both the operation to carry out the substrate 210 placed on each of the substrate mount 101a, the substrate mount 203a, and the substrate mount 30a, and the operation to carry the substrate 210 into each of the substrate mount 101a, the substrate mount 203a, and the substrate mount 30a. For example, in learning to acquire the transport control information 81 for the transport operation for the FOUP 101, the captured image 80 captured by the imager 41 that images the FOUP 101 and the captured image 80 captured by the imager 44 disposed on the substrate transport robot 20 are acquired as results of detection of the substrates 210 and the substrate mounts 101a in the FOUP 101. Then, the machine learning unit 61 uses the captured images 80 as inputs, which are the detection results, to perform machine learning using deep reinforcement learning using the DON so as to train the trained model 62 to output the transport control information 81. For example, the controller 60 trains the trained model 62 by performing a preset number of trial operations.

When the operation to carry the substrate 210 into the substrate mount 101a is learned, the operation of the substrate transport robot 20 is learned such that the position of the substrate mount 101a indicated by the target members 71 in the captured image 80 matches the position of the substrate holding hand 22 in the captured image 80, or the position of the substrate holding hand 22 detected based on the substrate 210 held by the substrate holding hand 22. When the operation to carry out the substrate 210 placed on the substrate mount 101a is learned, the operation of the substrate transport robot 20 is learned such that the positions of the target members 71 in the captured image 80 or the position of the substrate mount 101a detected based on the substrate 210 placed on the substrate mount 101a matches the position of the substrate holding hand 22 detected based on the substrate holding hand 22 in the captured image 80. The machine learning unit 61 of the controller 60 learns the transport control information 81 as a control amount in the transport operation for the load lock 203 and the transport control information 81 as a control amount in the transport operation for the aligner 30 using deep reinforcement learning, similarly to the FOUP 101.

That is, in this embodiment, the imager 40 images the substrates 210, the substrate mounts 101a and the target members 71, the substrate mount 203a and the target members 72, the substrate mount 30a and the target members 73, and the substrate transport robot 20 to detect the substrates 210, the substrate mounts 101a, the substrate mount 203a, the substrate mount 30a, and the substrate transport robot 20. In other words, in this embodiment, the captured images 80 are detection results obtained by detecting the substrates 210, the substrate mounts 101a, the substrate mount 203a, the substrate mount 30a, and the substrate transport robot 20. Then, the controller 60 acquires the transport control information 81 for controlling the transport operation of the substrate 210 to each of the FOUP 101, the load lock 203, and the aligner 30, using the trained model 62 generated by machine learning based on the captured image 80 captured by each of the imagers 41, 42, 43, and 44 and acquired as the detection results.

In this embodiment, the controller 60 controls the operation of the substrate transport robot 20 based on the transport control information 81 acquired using the trained model 62 generated by machine learning based on the captured images 80. That is, in the substrate transport system 100 according to this embodiment, the transport operation of the substrate transport robot 20 is controlled based on the acquired transport control information 81 such that the transport operation of the substrate transport robot 20 is taught by automatic teaching using machine learning based on the captured images 80. Therefore, in this embodiment, information indicating absolute position coordinates indicating the positions of the substrates 210 and the positions of the substrate mounts 101a, the substrate mount 203a, and the substrate mount 30a is not taught by an operator, and instead, the transport control information 81, which is an output from the trained model 62 to which the captured images 80 are input, is acquired such that a relative positional relationship indicating how the substrate transport robot 20 should be caused to operate appropriately from a state in which the current captured image 80 is acquired is automatically taught.

### Correction of Deviation in Transport Operation

In this embodiment, the controller 60 acquires the transport control information 81 using the trained model 62 generated by machine learning, and then performs the transport operation of the substrate 210 based on the acquired transport control information 81 to control the transport operation of the substrate transport robot 20 while correcting a deviation in the transport operation.

For example, as shown in FIG. 9, the substrates 210 placed on the substrate mount 101a, the substrate mount 203a, and the substrate mount 30a may be positionally deviated with respect to the substrate mount 101a, the substrate mount 203a, and the substrate mount 30a. FIG. 9 illustrates the positional deviation of the substrate 210 placed on the substrate mount 203a, and the substrate 210 with no positional deviation is indicated by a dotted line. When the transport operation of the positionally deviated substrate 210 is performed based on a set value, a deviation conceivably occurs in movement of the substrate 210 during the transport operation. Therefore, the machine learning unit 61 of the controller 60 uses the trained model 62 while the transport operation is performed to control the transport operation of the substrate transport robot 20 so as to correct the deviation in the transport operation based on the transport control information 81 acquired from the captured images 80. The controller 60 controls the transport operation while correcting the deviation to perform the transport operation so as to eliminate the positional deviations even when the positional deviations occur in the substrates 210 placed on the substrate mount 101a, the substrate mount 203a, and the substrate mount 30a.

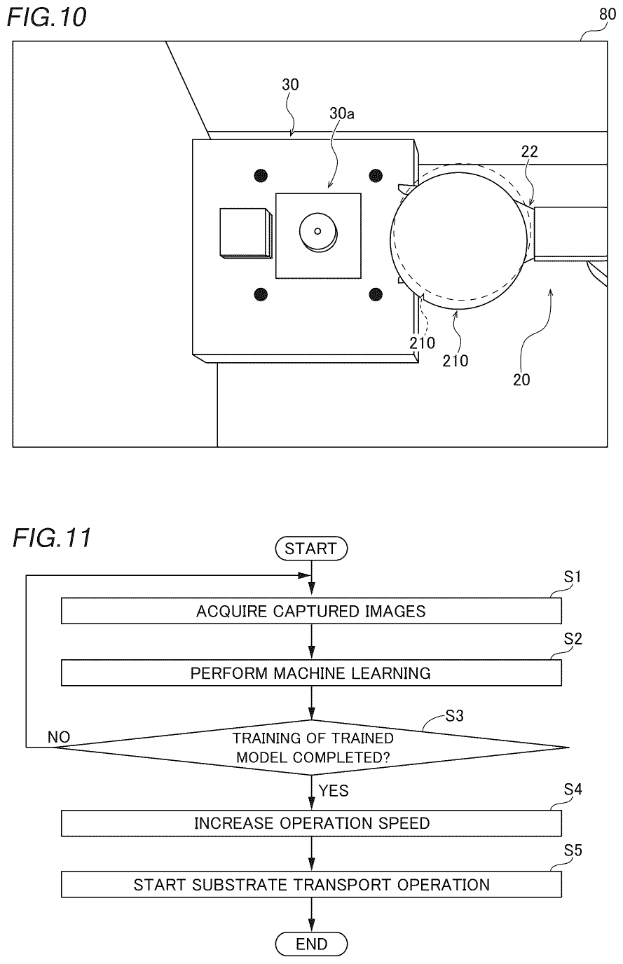

As shown in FIG. 10, the substrate 210 held by the substrate holding hand 22 may be positionally deviated with respect to the substrate holding hand 22 of the substrate transport robot 20. In FIG. 10, the substrate 210 with no positional deviation is indicated by a dotted line, similarly to FIG. 9. Even in such a case, the controller 60 controls the transport operation so as to correct the deviation in the transport operation of the substrate transport robot 20 based on the transport control information 81 acquired from the captured images 80 using the trained model 62 while performing the transport operation, so as to prevent any deviation in movement of the substrate 210 during the transport operation.

When the machine learning unit 61 generates the trained model 62 by machine learning using the captured images 80 as inputs, the controller 60 controls the transport operation of the substrate transport robot 20 at an operation speed lower than the operation speed of the normal transport operation until training of the trained model 62 is completed. That is, the controller 60 acquires the transport control information 81 for controlling the transport operation of the substrate transport robot 20 by repeatedly attempting the transport operation while performing machine learning using the captured images 80 as inputs, with the operation speed of the transport operation set to a relatively low value.

When training of the trained model 62 by deep reinforcement learning is completed, the controller 60 performs the transport operation of the substrate transport robot 20 at a relatively high operation speed based on the transport control information 81 from the trained model 62, which has been trained. For example, the controller 60 determines that training of the trained model 62 is completed when a preset number of trial operations are completed.

For example, when the plurality of substrates 210 stored in the FOUP 101 are sequentially transported, the controller 60 performs machine learning to generate the trained model 62 using deep reinforcement learning by performing a predetermined number of trials based on the captured images 80 while maintaining the operation speed of the transport operation relatively low before the transport operation of the substrates 210 is performed. The controller 60 then performs another predetermined number of transport operations while maintaining the operation speed of the transport operation relatively low, based on the transport control information 81 output from the generated trained model 62, to perform machine learning again to update the trained model 62. After training of the trained model 62 is completed, the controller 60 controls the transport operation of the substrate transport robot 20 at a normal operation speed, which is a relatively high operation speed. As an example, the trained model 62 is generated by performing machine learning through a predetermined number of trials before the substrate transport system 100 is shipped from a factory, and the trained model 62 is trained by performing machine learning through another predetermined number of trials after the substrate transport system 100 is installed.

### Substrate Transport Method

A control process for a substrate transport method using the substrate transport system 100 according to this embodiment is now described with reference to FIG. 11. The control process for the substrate transport method according to this embodiment is executed by the controller 60 of the substrate transport system 100.

First, in step S1, the captured images 80 are acquired. Specifically, the captured images 80 are acquired as the detection results, in which the substrates 210, the substrate mounts 101a, the substrate mount 203a, the substrate mount 30a, the target members 71, the target members 72, the target members 73, and the substrate transport robot 20 are imaged, such that the substrates 210, the substrate mounts 101a, the substrate mount 203a, the substrate mount 30a, and the substrate transport robot 20 are detected. In step S1, the captured images 80 are acquired while the substrate transport robot 20 is operated at a relatively low operation speed.

Next, in step S2, machine learning is performed to generate the trained model 62. Specifically, machine learning is performed using deep reinforcement learning such that the transport control information 81 for controlling the transport operation of the substrate transport robot 20 is output using the captured images 80 acquired in step S1 as inputs.

Next, in step S3, it is determined whether or not training of the trained model 62 has been completed. When it is determined that training of the trained model 62 has been completed, the process advances to step S4. When it is not determined that training of the trained model 62 has been completed, the process returns to step S1. In step S3, it is determined whether or not training of the trained model 62 has been completed based on whether or not machine learning has been performed a predetermined number of times, for example.

In step S4, the operation speed of the substrate transport robot 20 is set to a relatively high value.

Next, in step S5, the transport operation of the substrate transport robot 20 is started based on the trained model 62 generated by the control process from step S1 to step S3. That is, the transport operation is started based on the transport control information 81 from the trained model 62 generated by machine learning using the captured images 80.

### Advantageous Effects of This Embodiment

The substrate transport system 100 is configured to generate the trained model 62 by machine learning to output the transport control information 81 for controlling the transport operation of the substrate 210 by the substrate transport robot 20 using the captured images 80 as inputs, which are the results of detection of the substrates 210, the substrate mounts 101a, the substrate mount 203a, and the substrate mount 30a, as described above. Accordingly, the transport operation of the substrate 210 can be automatically controlled based on the output from the trained model 62 generated by machine learning. Consequently, the effort required by the operator to control the transport operation of the substrate 210 by the substrate transport robot 20 can be reduced, as compared with a case in which the transport operation of the substrate 210 to the substrate mount 101a, the substrate mount 203a, and the substrate mount 30a is manually taught.

The controller 60 is configured or programmed to generate the trained model 62 by machine learning using deep reinforcement learning. Accordingly, the transport operation of the substrate transport robot 20 can be controlled using the trained model 62 trained through machine learning using deep reinforcement learning, which is reinforcement learning using deep learning. Therefore, in machine learning for generating the trained model 62, feature amounts required for reinforcement learning are extracted using deep learning such that the effort required by the operator to control the transport operation of the substrate 210 by the substrate transport robot 20 can be further reduced.

The controller 60 is configured or programmed to generate the trained model 62 by machine learning to output the transport control information 81 including the teaching information for aligning the coordinate axes of the substrate transport robot 20 with the coordinate axes of the positions of the substrate mounts 101a, the substrate mount 203a, and the substrate mount 30a, using the captured images 80 as inputs, which are the results of detection. Accordingly, the transport operation of the substrate transport robot 20 can be automatically taught based on the transport control information 81 including the teaching information output from the trained model 62, and thus the effort required by the operator to control the transport operation of the substrate 210 by the substrate transport robot 20 can be reduced.

The imager 40, which serves as a detector, is configured to detect the substrates 210, the substrate mounts 101a, the substrate mount 203a, the substrate mount 30a, and the substrate transport robot 20 by imaging the substrate mounts 101a, the substrate mount 203a, the substrate mount 30a, and the substrate transport robot 20. The controller 60 is configured or programmed to generate the trained model 62 to output the transport control information 81 using, as inputs, the captured images 80 that are the results of detection of the substrates 210, the substrate mounts 101a, the substrate mount 203a, and the substrate mount 30a, and the captured image 80 that is the result of detection of the substrate transport robot 20. Accordingly, the trained model 62 can be trained to output the transport control information 81 using, as inputs, the captured images 80 in which the substrates 210, the substrate mounts 101a, the substrate mount 203a, and the substrate mount 30a as well as the substrate transport robot 20 are imaged, and thus the accuracy of the transport control information 81 output from the trained model 62 can be improved. Therefore, the transport operation of the substrate transport robot 20 can be more accurately controlled.

The controller 60 is configured or programmed to also define and function as the robot controller to control the transport operation of the substrate transport robot 20. Furthermore, the controller 60 is configured or programmed to acquire the transport control information 81 using the trained model 62, and control the transport operation of the substrate transport robot 20 while correcting a deviation in the transport operation by performing the transport operation of the substrate 210 based on the acquired transport control information 81. Accordingly, even when the deviation in the transport operation such as a deviation in the operation of the substrate transport robot 20 or a deviation in the placement position of the substrate 210 occurs, the trained model 62 can be used to control the transport operation of the substrate transport robot 20 so as to correct the deviation. Therefore, the deviation in the transport operation is automatically corrected such that the transport operation of the substrate transport robot 20 can be accurately performed.

The substrate transport system 100 includes the imager 40 to image at least one of the substrate(s) 210, the substrate mounts 101a, 203a, and 30a, or the target members 71, 72, and 73 configured to indicate the positions of the substrate mounts 101a, 203a, and 30a. The controller 60 is configured or programmed to generate the trained model 62 by machine learning to output the transport control information 81 using, as an input, the captured image 80 acquired by the imager 40 as the detection result. Accordingly, as compared with detection using a position sensor such as a photoelectronic sensor, the substrate(s) 210, the substrate mounts 101a, the substrate mount 203a, the substrate mount 30a, the target members 71, the target members 72, and the target members 73 can be easily detected by imaging by the imager 40. Therefore, the accuracy of identification using the trained model 62 generated by machine learning using the captured images 80 as inputs can be improved, and thus the accuracy of the transport operation of the substrate 210 by the substrate transport robot 20 can be improved.

The substrate transport system 100 includes the target members 71, 72, and 73 to indicate the positions of the substrate mounts 101a, 203a, and 30a. The imager 40 is configured to image the target members 71, 72, and 73. The controller 60 is configured or programmed to generate the trained model 62 by machine learning to output the transport control information 81 using, as inputs, the captured images 80 including the target members 71, 72, and 73 acquired as the detection results. Accordingly, even when the shapes of the substrate mounts 101a, 203a, and 30a are unclear in the captured images 80, the trained model 62 can acquire the transport control information 81 based on the captured images 80 including the target members 71, 72, and 73. Therefore, when the shapes of the substrate mounts 101a, 203a, and 30a are unclear in the captured images 80, a decrease in the accuracy of control of the transport operation using the trained model 62 generated by machine learning based on the captured images 80 can be reduced or prevented.

The target members 71, 72, and 73 have the predetermined shapes in the captured images 80 so as to be identified in machine learning for generating the trained model 62. Accordingly, the target members 71, 72, and 73 have the predetermined shapes, and thus the target members 71, 72, and 73 can be easily detected from the captured images 80. Therefore, the positions of the substrate mounts 101a, 203a, and 30a in the captured images 80 can be easily detected, and thus the accuracy of the trained model 62 generated by machine learning can be improved. Consequently, the transport operation of the substrate transport robot 20 using the trained model 62 can be even more accurately controlled.

The substrate transport system 100 includes the transport chamber 10 including the substrate transport robot 20 therein to transport the substrate 210 therein.

The imager 40 is in the transport chamber 10.

Accordingly, the transport operation of the substrate transport robot 20 can be controlled using the trained model 62 based on the captured images 80 captured inside the transport chamber 10. Therefore, the backgrounds in the captured images 80 can be maintained constant, and thus the transport operation of the substrate transport robot 20 using the trained model 62 can be more accurately controlled.

The imager 40 includes the imagers 41, 42, and 43 as the transport chamber imagers in the transport chamber 10, and the imager 44 as the robot imager on the substrate transport robot 20. The controller 60 is configured or programmed to generate the trained model 62 by machine learning to output the transport control information 81 using the captured images 80 captured by the imagers 41, 42, and 43 and the captured image 80 captured by the imager 44 as inputs. Accordingly, the imager 40 is disposed in the transport chamber 10 and on the substrate transport robot 20, and thus machine learning can be performed to generate the trained model 62 using the captured images 80 captured from different angles as inputs. Therefore, the accuracy of the trained model 62 can be improved, and thus the transport operation of the substrate transport robot 20 using the trained model 62 can be more accurately controlled.

The imagers 41, 42, and 43, which serve as the transport chamber imagers, are on the upper portion of the transport chamber 10. Accordingly, the possibility that the imagers 41, 42, and 43 interfere with the operation of the substrate transport robot 20 can be reduced or prevented, and the substrate mounts 101a, 203a, and 30a can be imaged from above. Therefore, the visibility of the substrate mounts 101a, 203a, and 30a in the captured images 80 is improved, and thus the transport operation of the substrate transport robot 20 using the trained model 62 based on the captured images 80 can be more accurately controlled.

The substrate transport robot 20 is configured to perform the transport operation of the substrate 210 to the FOUP 101, which serves as the substrate storage container configured to store the substrates 210, in the transport chamber 10. The imager 41 is configured to image at least one of the substrates 210 stored in the FOUP 101, the substrate mounts 101a on which the substrates 210 are placed in the FOUP 101, or the target members 71 configured to indicate the positions of the substrate mounts 101a in the FOUP 101. The controller 60 is configured or programmed to generate the trained model 62 by machine learning to output the transport control information 81 using, as an input, the captured image 80 including at least one of the substrates 210 stored in the FOUP 101, the substrate mounts 101a on which the substrates 210 are placed in the FOUP 101, or the target members 71 configured to indicate the positions of the substrate mounts 101a in the FOUP 101. Accordingly, the transport control information 81 for controlling the transport operation of the substrate transport robot 20 for the FOUP 101 can be acquired using the trained model 62, and thus the effort required by the operator to control the transport operation for the FOUP 101 can be reduced.

The substrate transport robot 20 is configured to perform the transport operation of the substrate 210 between the FOUP 101, which serves as the substrate storage container, and the load lock 203, which serves as the processing standby unit, in which the substrate 210 is placed to be delivered to the processing apparatus 201 configured to process the substrate 210. The imager 42 is configured to image at least one of the substrate 210 placed on the substrate mount 203a in the load lock 203, the substrate mount 203a in the load lock 203, or the target members 72 configured to indicate the position of the substrate mount 203a in the load lock 203. The controller 60 is configured or programmed to generate the trained model 62 by machine learning to output the transport control information 81 using, as an input, the captured image 80 including at least one of the substrate 210 placed on the substrate mount 203a in the load lock 203, the substrate mount 203a in the load lock 203, or the target members 72 configured to indicate the position of the substrate mount 203a in the load lock 203. Accordingly, the transport operation of the substrate transport robot 20 to the load lock 203 can be controlled using the trained model 62 generated by machine learning based on the captured image 80, and thus the effort required by the operator to control the transport operation to the load lock 203 can be reduced.

The controller 60 is configured or programmed to also define and function as the robot controller to control the transport operation of the substrate transport robot 20. Furthermore, the controller 60 is configured or programmed to, when generating the trained model 62 by machine learning using the captured images 80, which are the detection results, as inputs, control the transport operation of the substrate transport robot 20 at a relatively low operation speed until training of the trained model 62 is completed. Accordingly, the operation speed is relatively low while the trained model 62 is trained such that blurring of the captured images 80 acquired for machine learning can be reduced or prevented, and thus the accuracy of the trained model 62 generated by machine learning can be improved. Therefore, the accuracy of control of the transport operation based on the trained model 62 can be improved.

### MODIFIED EXAMPLES

The embodiment disclosed this time must be considered as illustrative in all points and not restrictive. The scope of the present disclosure is not shown by the above description of the embodiment but by the scope of claims for patent, and all modifications (modified examples) within the meaning and scope equivalent to the scope of claims for patent are further included.

For example, while the example in which the controller 60 that controls the transport operation of the substrate transport robot 20 generates the trained model 62 by performing machine learning using the DQN, which is reinforcement learning using deep learning, has been shown in the aforementioned embodiment, the present disclosure is not limited to this. In the present disclosure, the trained model may be trained by a control device that is a learning device separate from the controller that controls the operation of the substrate transport robot. In such a case, transport control information acquired in the learning device based on the trained model is output to the controller that controls the transport operation such that the transport operation of the substrate transport robot is controlled based on the transport control information. Furthermore, a machine learning algorithm for generating a trained model is not limited to the DQN. For example, reinforcement learning may be performed using a multilayer fully connected neural network, which is a form of deep reinforcement learning other than the DQN. Moreover, machine learning of the trained model may be performed using reinforcement learning such as Q-learning, which does not use deep learning. In addition, in machine learning, completion of training and updating of the trained model may be determined when a predetermined operating time has elapsed, rather than after a predetermined number of trials.

While the example in which using, as inputs, the captured images 80, which are the detection results obtained by imaging the substrates 210, the substrate mounts 101a of the FOUP 101, the substrate mount 203a of the load lock 203, the substrate mount 30a of the aligner 30, the target members 71, the target members 72, and the target members 73 as well as the substrate transport robot 20 using the imager 40, which serves as the detector, machine learning of the trained model 62 is performed to output the transport control information 81 has been shown in the aforementioned embodiment, the present disclosure is not limited to this. In the present disclosure, the captured images used for learning may not include the substrate transport robot. The captured images are only required to include at least one of the substrates, the substrate mounts, or the target members. For example, when the carry-out operation of the substrate is learned, machine learning may be performed based on the captured image of the substrate captured such that only the placed substrate is detected. When the carry-in operation to place the substrate is learned, machine learning may be performed based on the captured image of either the substrate mount or the target members captured such that the substrate mount is detected. That is, the substrate transport system according to the present disclosure may not include the target members. The substrate mount itself may be detected in the captured image without disposing the target members. Alternatively, instead of imaging by the imager, a position sensor such as a photoelectronic sensor that emits detection light may be provided as the detector. In such a case, the trained model is generated to output the transport control information using the detection results of the position sensor as inputs.

While the example in which in the transport operation of the substrate transport robot 20, both the operation to carry in the substrate 210 and the operation to carry out the substrate 210 are learned such that the transport operation including both the operation to carry in the substrate 210 and the operation to carry out the substrate 210 is controlled has been shown in the aforementioned embodiment, the present disclosure is not limited to this. In the present disclosure, the transport control information for controlling either the operation to carry in the substrate or the operation to carry out the substrate may be learned.

While the example in which the transport operation of the substrate 210 based on the transport control information 81 is performed such that the transport operation of the substrate transport robot 20 is controlled while the deviation in the transport operation is corrected has been shown in the aforementioned embodiment, the present disclosure is not limited to this. In the present disclosure, separately from learning by machine learning, the deviation in the transport operation may be corrected by an arithmetic process such as a rule-based algorithm based on the results of detection of the substrate. Furthermore, while the example in which while the transport operation is performed, the transport operation is controlled to correct the deviation in the transport operation of the substrate transport robot based on the transport control information acquired from the captured images, which are the detection results, using the trained model has been shown in the aforementioned embodiment, the trained model may not be used while the transport operation is performed. That is, the control amount for performing the transport operation may be acquired by performing machine learning in advance, and the transport operation may be controlled using the control amount based on the transport control information acquired by machine learning as a set value. In other words, the transport operation may be automatically taught by machine learning, and the transport operation itself may be performed based on the set value as a fixed value set by automatic teaching.

While the example in which the target members 71, the target members 72, and the target members 73 are circular plate-shaped members has been shown in the aforementioned embodiment, the present disclosure is not limited to this. In the present disclosure, the target members may be spherical, cylindrical, or prism-shaped with a polygonal cross-section, or may be solid bodies having a predetermined shape such as a cross. Alternatively, the target members may be marker members such as AR markers. The target members may be removed after learning is completed. Furthermore, the target members may be provided to indicate not only the positions of the substrate mounts but also the position of the substrate transport robot or the position of the substrate holding hand. In such a case, machine learning may be performed by detecting the substrate transport robot based on the result of detection of the target members or the captured image. Alternatively, the target member transported by the substrate transport robot may be placed in place of the substrate, and machine learning may be performed based on the result of detection of the target member placed in place of the substrate or the captured image. Alternatively, the target member may be placed at a position at which the substrate of the substrate mount is placed, such as inside the substrate storage container. The number of target members for one substrate mount may be one or more.

While the example in which the transport chamber 10 is provided in which the substrate transport robot 20, the imager 40, and the illuminators 50 are disposed has been shown in the aforementioned embodiment, the present disclosure is not limited to this. In the present disclosure, the transport chamber may not be provided. Furthermore, either the imager or the illuminators may be disposed outside the transport chamber in which the substrate is transported. For example, when the substrate transport method according to the present disclosure is executed in the transport chamber of the processing apparatus that processes the substrate, a ceiling member of the transport chamber of the processing apparatus may be made of a transparent material such as glass, and an imager and illuminators may be placed on an upper portion of the outside of the transport chamber. Alternatively, when the ceiling member of the transport chamber is made of a transparent material, an external light source may be used to eliminate the need for the illuminators.

While the example in which the imagers 41, the imagers 42, and the imager 43 are provided on the upper portion of the transport chamber 10, and the imager 44 is provided on the substrate holding hand 22 of the substrate transport robot 20 has been shown in the aforementioned embodiment, the present disclosure is not limited to this. In the present disclosure, the imager may not be provided on the substrate transport robot. Furthermore, the imagers may not be provided in the transport chamber. When the imagers are provided in the transport chamber, the imagers may be provided on a lower portion of the transport chamber. Moreover, the imagers may include stereo cameras or 3D cameras such as time-of-flight (TOF) cameras. In addition, a plurality of imagers may be provided for one imaging target. For example, a plurality of imagers may be provided to image one substrate mount. Besides, the imagers may be configured to detect infrared light. In such a case, illuminators that emit infrared light and target members that reflect infrared light may be provided. Additionally, the imager may be provided inside the substrate storage container, or inside the processing standby unit.

While the example in which the operation speed is maintained relatively low until training of the trained model 62 is completed has been shown in the aforementioned embodiment, the present disclosure is not limited to this. In the present disclosure, even when the trained model is being trained, the operation speed of the transport operation may not be maintained relatively low.

While the example in which the substrate transport robot 20 including the horizontal articulated robot arm 21 is provided has been shown in the aforementioned embodiment, the present disclosure is not limited to this. In the present disclosure, the substrate transport robot may include a vertically articulated robot arm instead of the horizontally articulated robot arm. Moreover, the substrate transport robot may include a linear movement mechanism such as a slide mechanism.

While the example in which the substrate transport system 100 according to the present disclosure is an EFEM that transports the substrate 210 to the processing apparatus 201 has been shown in the aforementioned embodiment, the present disclosure is not limited to this. In the present disclosure, the substrate transport system may be other than an EFEM. For example, the substrate transport system may be a stocker or sorter that transports substrates from one substrate storage container to another. Furthermore, the substrate transport system may transport substrates that have been transported by a belt conveyor or the like, rather than by the substrate storage container, to the substrate storage container or the substrate mounts. Moreover, the substrate transport method according to the present disclosure may be applied to a system that transports substrates on the processing apparatus side. That is, when substrates are transported between the load locks and the processing modules, the substrates may be transported by the substrate transport method according to the present disclosure.

While the example in which the illuminators 50 emit illumination light at the timing at which the imager 40 captures an image has been shown in the aforementioned embodiment, the present disclosure is not limited to this. In the present disclosure, illumination light may be constantly emitted from the illuminators. Furthermore, emission of the illumination light may be controlled by a control process performed by the controller based on the captured images. For example, a control to change the light intensity, wavelength, etc. of the illumination light may be performed based on the luminance values of the captured images.

While the example in which two illuminators 50 including LEDS that emit yellow light as illumination light are provided has been shown in the aforementioned embodiment, the present disclosure is not limited to this. In the present disclosure, the illuminators may include light source devices other than LEDs. Furthermore, the illumination light emitted from the illuminators may have a wavelength of a predetermined color, such as orange, in addition to yellow. Moreover, the illuminators may emit light including a plurality of wavelengths, such as white light. In addition, the illumination light may be light of a wavelength other than visible light, such as infrared light. Besides, the number of illuminators may be one, or three or more.

While the example in which three FOUPs 101 are attached to the transport chamber 10 of the substrate transport system 100 as the substrate storage containers, and three imagers 40 are disposed corresponding to the FOUPs 101 has been shown in the aforementioned embodiment, the present disclosure is not limited to this. In the present disclosure, the number of substrate storage containers attached to the transport chamber may be two or less, or may be four or more. Furthermore, one imager may be provided for a plurality of substrate storage containers. In such a case, the common imager images substrates transported to the plurality of substrate storage containers.

While the example in which the trained model 62 is trained by machine learning to output the transport control information 81 using the captured images 80 captured by the imager 40 as inputs has been shown in the aforementioned embodiment, the present disclosure is not limited to this. In the present disclosure, image processing such as noise removal, edge enhancement, and contrast change may be performed in advance on the captured images to be input to the trained model before the captured images are input to the trained model. In addition, an output from the trained model may not be the transport control information including command values for operating the robot arm, but may be transport control information including coordinates indicating the positions of the detected substrate, the substrate mount, and the substrate transport robot.

The functionality of the elements disclosed herein may be implemented using circuitry or processing circuitry which includes general purpose processors, special purpose processors, integrated circuits, ASICs (“Application Specific Integrated Circuits”), conventional circuitry and/or combinations thereof which are configured or programmed to perform the disclosed functionality. Processors are considered processing circuitry or circuitry as they include transistors and other circuitry therein. The processor may be a programmed processor which executes a program stored in a memory. In the disclosure, the circuitry, units, or means are hardware that carry out or are programmed to perform the recited functionality. The hardware may be any hardware disclosed herein or otherwise known which is programmed or configured to carry out the recited functionality. When the hardware is a processor which may be considered a type of circuitry, the circuitry, means, or units are a combination of hardware and software, the software being used to configure the hardware and/or processor.

### ASPECTS

It will be appreciated by those skilled in the art that the exemplary embodiments described above are specific examples of the following aspects.

### (Item 1)

A substrate transport system comprising:
a substrate transport robot;
a detector to detect at least one of a substrate transported by the substrate transport robot or a substrate mount on which the substrate is placed; and
a controller configured or programmed to generate a trained model by machine learning to output transport control information for controlling transport operation of the substrate by the substrate transport robot using a result of detection of the at least one of the substrate or the substrate mount by the detector as an input.

### (Item 2)

The substrate transport system according to item 1, wherein the controller is configured or programmed to generate the trained model by machine learning using deep reinforcement learning.

### (Item 3)

The substrate transport system according to item 1 or 2, wherein the controller is configured or programmed to generate the trained model by machine learning to output the transport control information including teaching information for aligning coordinate axes of the substrate transport robot with coordinate axes of a position of the substrate mount using the result of detection as an input.

### (Item 4)

The substrate transport system according to any one of items 1 to 3, wherein
the detector is configured to detect the substrate transport robot in addition to the at least one of the substrate or the substrate mount; and
the controller is configured or programmed to generate the trained model to output the transport control information using, as inputs, the result of detection of the at least one of the substrate or the substrate mount, and a result of detection of the substrate transport robot.

### (Item 5)

The substrate transport system according to any one of items 1 to 4, wherein the controller is configured or programmed to:
also define and function as a robot controller to control the transport operation of the substrate transport robot; and
acquire the transport control information using the trained model, and control the transport operation of the substrate transport robot while correcting a deviation in the transport operation by performing the transport operation of the substrate based on the acquired transport control information.

### (Item 6)

The substrate transport system according to any one of items 1 to 5, wherein
the detector includes an imager to image at least one of the substrate, the substrate mount, or a target member configured to indicate a position of the substrate mount; and
the controller is configured or programmed to generate the trained model by machine learning to output the transport control information using, as an input, a captured image acquired by the imager as the result of detection by the detector.

### (Item 7)

The substrate transport system according to item 6, further comprising:
the target member to indicate the position of the substrate mount; wherein
the imager is configured to image the target member; and
the controller is configured or programmed to generate the trained model by machine learning to output the transport control information using, as an input, the captured image including the target member acquired as the result of detection.

### (Item 8)

The substrate transport system according to item 7, wherein the target member has a predetermined shape in the captured image so as to be identified in machine learning for generating the trained model.

### (Item 9)

The substrate transport system according to any one of claims 6 to 8, further comprising:
a transport chamber including the substrate transport robot therein to transport the substrate therein; wherein the imager is in the transport chamber.

### (Item 10)

The substrate transport system according to item 9, wherein
the imager includes a transport chamber imager in the transport chamber, and a robot imager on the substrate transport robot; and
the controller is configured or programmed to generate the trained model by machine learning to output the transport control information using the captured image captured by the transport chamber imager and the captured image captured by the robot imager as inputs.

### (Item 11)

The substrate transport system according to item 10, wherein the transport chamber imager is on an upper portion of the transport chamber.

### (Item 12)

The substrate transport system according to any one of items 9 to 11, wherein
the substrate transport robot is configured to perform the transport operation of the substrate to a substrate storage container configured to store the substrate, in the transport chamber;
the imager is configured to image at least one of the substrate stored in the substrate storage container, the substrate mount on which the substrate is placed in the substrate storage container, or the target member configured to indicate the position of the substrate mount in the substrate storage container; and
the controller is configured or programmed to generate the trained model by machine learning to output the transport control information using, as an input, the captured image including at least one of the substrate stored in the substrate storage container, the substrate mount on which the substrate is placed in the substrate storage container, or the target member configured to indicate the position of the substrate mount in the substrate storage container.

### (Item 13)

The substrate transport system according to item 12, wherein
the substrate transport robot is configured to perform the transport operation of the substrate between the substrate storage container and a processing standby unit in which the substrate is placed to be delivered to a processing apparatus configured to process the substrate;
the imager is configured to image at least one of the substrate placed on the substrate mount in the processing standby unit, the substrate mount in the processing standby unit, or the target member configured to indicate the position of the substrate mount in the processing standby unit; and
the controller is configured or programmed to generate the trained model by machine learning to output the transport control information using, as an input, the captured image including at least one of the substrate placed on the substrate mount in the processing standby unit, the substrate mount in the processing standby unit, or the target member configured to indicate the position of the substrate mount in the processing standby unit.

### (Item 14)

The substrate transport system according to any one of items 1 to 13, wherein the controller is configured or programmed to:
also define and function as a robot controller to control the transport operation of the substrate transport robot; and
when generating the trained model by machine learning using the result of detection as an input, control the transport operation of the substrate transport robot at a relatively low operation speed until training of the trained model is completed.

### (Item 15)

A substrate transport method comprising:
detecting at least one of a substrate transported by a substrate transport robot or a substrate mount on which the substrate is placed; and
generating a trained model by machine learning to output transport control information for controlling transport operation of the substrate by the substrate transport robot using a result of detection of the at least one of the substrate or the substrate mount by the detector as an input.

1. A substrate transport system comprising:
a substrate transport robot;
a detector to detect at least one of a substrate transported by the substrate transport robot or a substrate mount on which the substrate is placed; and
a controller configured or programmed to generate a trained model by machine learning to output transport control information for controlling transport operation of the substrate by the substrate transport robot using a result of detection of the at least one of the substrate or the substrate mount by the detector as an input.

2. The substrate transport system according to claim 1, wherein the controller is configured or programmed to generate the trained model by machine learning using deep reinforcement learning.

3. The substrate transport system according to claim 1, wherein the controller is configured or programmed to generate the trained model by machine learning to output the transport control information including teaching information for aligning coordinate axes of the substrate transport robot with coordinate axes of a position of the substrate mount using the result of detection as an input.

4. The substrate transport system according to claim 1, wherein
the detector is configured to detect the substrate transport robot in addition to the at least one of the substrate or the substrate mount; and
the controller is configured or programmed to generate the trained model to output the transport control information using, as inputs, the result of detection of the at least one of the substrate or the substrate mount, and a result of detection of the substrate transport robot.

5. The substrate transport system according to claim 1, wherein the controller is configured or programmed to:
also define and function as a robot controller to control the transport operation of the substrate transport robot; and
acquire the transport control information using the trained model, and control the transport operation of the substrate transport robot while correcting a deviation in the transport operation by performing the transport operation of the substrate based on the acquired transport control information.

6. The substrate transport system according to claim 1, wherein
the detector includes an imager to image at least one of the substrate, the substrate mount, or a target member configured to indicate a position of the substrate mount; and
the controller is configured or programmed to generate the trained model by machine learning to output the transport control information using, as an input, a captured image acquired by the imager as the result of detection by the detector.

7. The substrate transport system according to claim 6, further comprising:
the target member to indicate the position of the substrate mount; wherein
the imager is configured to image the target member; and
the controller is configured or programmed to generate the trained model by machine learning to output the transport control information using, as an input, the captured image including the target member acquired as the result of detection.

8. The substrate transport system according to claim 7, wherein the target member has a predetermined shape in the captured image so as to be identified in machine learning for generating the trained model.

9. The substrate transport system according to claim 6, further comprising:
a transport chamber including the substrate transport robot therein to transport the substrate therein; wherein
the imager is in the transport chamber.

10. The substrate transport system according to claim 9, wherein
the imager includes a transport chamber imager in the transport chamber, and a robot imager on the substrate transport robot; and
the controller is configured or programmed to generate the trained model by machine learning to output the transport control information using the captured image captured by the transport chamber imager and the captured image captured by the robot imager as inputs.

11. The substrate transport system according to claim 10, wherein the transport chamber imager is on an upper portion of the transport chamber.

12. The substrate transport system according to claim 9, wherein
the substrate transport robot is configured to perform the transport operation of the substrate to a substrate storage container configured to store the substrate, in the transport chamber;
the imager is configured to image at least one of the substrate stored in the substrate storage container, the substrate mount on which the substrate is placed in the substrate storage container, or the target member configured to indicate the position of the substrate mount in the substrate storage container; and
the controller is configured or programmed to generate the trained model by machine learning to output the transport control information using, as an input, the captured image including at least one of the substrate stored in the substrate storage container, the substrate mount on which the substrate is placed in the substrate storage container, or the target member configured to indicate the position of the substrate mount in the substrate storage container.

13. The substrate transport system according to claim 12, wherein
the substrate transport robot is configured to perform the transport operation of the substrate between the substrate storage container and a processing standby unit in which the substrate is placed to be delivered to a processing apparatus configured to process the substrate;
the imager is configured to image at least one of the substrate placed on the substrate mount in the processing standby unit, the substrate mount in the processing standby unit, or the target member configured to indicate the position of the substrate mount in the processing standby unit; and
the controller is configured or programmed to generate the trained model by machine learning to output the transport control information using, as an input, the captured image including at least one of the substrate placed on the substrate mount in the processing standby unit, the substrate mount in the processing standby unit, or the target member configured to indicate the position of the substrate mount in the processing standby unit.

14. The substrate transport system according to claim 1, wherein the controller is configured or programmed to:
also define and function as a robot controller to control the transport operation of the substrate transport robot; and
when generating the trained model by machine learning using the result of detection as an input, control the transport operation of the substrate transport robot at a relatively low operation speed until training of the trained model is completed.

15. A substrate transport method comprising:
detecting at least one of a substrate transported by a substrate transport robot or a substrate mount on which the substrate is placed; and
generating a trained model by machine learning to output transport control information for controlling transport operation of the substrate by the substrate transport robot using a result of detection of the at least one of the substrate or the substrate mount by the detector as an input.
